(19) United States
(12) Patent Application Publication
(10) Pub. No.: US 2017/0179201 A1
(43) Pub. Date: Jun. 22, 2017

(54) PROCESSES FOR FABRICATING ORGANIC PHOTODETECTORS AND RELATED PHOTODETECTORS AND SYSTEMS

(71) Applicant: General Electric Company, Schenectady, NY (US)

(72) Inventors: Ri-an Zhao, Niskayuna, NY (US); Kwang Hyup An, Rexford, NY (US)

(21) Appl. No.: 14/970,917

(22) Filed: Dec. 16, 2015

(51) Int. Cl. H01L 27/30; H01L 51/44; G01T 1/20; H01L 51/00

(52) U.S. Cl. CPC H01L 27/308; H01L 51/0017; H01L 27/307; H01L 51/0021; H01L 51/442; H01L 51/448; G01T 1/2006; H01L 2251/305; H01L 51/0046

(57) ABSTRACT

A process for fabricating an organic photodetector is presented. The process includes providing an array of thin film transistor assemblies, each thin film transistor assembly including a first electrode disposed on a thin film transistor; disposing an organic semiconductor layer on the array; disposing a second electrode layer including a first inorganic material on the organic semiconductor layer through a shadow mask to form a first etch stop layer; and removing portions of the organic semiconductor layer unprotected by the first etch stop layer using a dry etching process to form a multilayered structure. An organic photodetector, for example an organic x-ray detector fabricated by the process is further presented. An x-ray system including the organic x-ray detector is also presented.

### BACKGROUND

Embodiments of the present disclosure generally relate to organic photodetectors. More particularly, embodiments of the present disclosure relate to processes for fabricating organic photodetectors.

Photodetectors may be used in a variety of imaging applications such as molecular and optical imaging systems. For example, photodetectors may be used in medical imaging applications such as computed tomography, positron emission tomography, magnetic resonance imaging, and digital radiography. Photodetectors with continuous photodiodes may have an increased fill factor and potentially higher quantum efficiency. Continuous photodiodes typically include organic photodiodes (OPDs).

Generally, the organic photodetectors may be manufactured by non-selectively coating one or more OPD layers onto a thin film transistor (TFT) array, resulting in a continuous OPD layer configuration. The OPD layers may be applied by large area coating methods such as slot die coating, spray coating. The OPD layers outside of the TFT array may be removed or patterned in order to expose an area (e.g., an area around the TFT array) for providing external electrical connections and an encapsulation for long term reliability of the photodetector. Patterning can be done using various wet-etching processes, for example photolithography process. However, the solvents or other wet chemicals used may interact with OPD layers and degrade OPD performance

Therefore, there is a need for improved processes for fabricating organic photodetectors and organic x-ray detectors.

### BRIEF DESCRIPTION

One aspect of the specification presents a process for fabricating an organic photodetector. The process includes providing an array of thin film transistor assemblies, each thin film transistor assembly including a first electrode disposed on a thin film transistor; disposing an organic semiconductor layer on the array; disposing a second electrode layer comprising a first inorganic material on the organic semiconductor layer through a shadow mask to form a first etch stop layer; and removing portions of the organic semiconductor layer unprotected by the first etch stop layer using a dry etching process to form a multilayered structure. In one aspect of the specification, an organic photodetector fabricated by the process is provided.

In one aspect of the specification, a process for fabricating an organic photodetector includes providing an array of thin film transistor assemblies, each thin film transistor assembly including a first electrode layer disposed on a thin film transistor; disposing an organic semiconductor layer on the array; disposing a second electrode layer including a first inorganic material on the organic semiconductor layer through a shadow mask to form a first etch stop layer; removing portions of the organic semiconductor layer unprotected by the first etch stop layer using a dry etching process; disposing a planarization layer on the second electrode layer; disposing a barrier layer including a second inorganic material on the planarization layer through the shadow mask to form a second etch stop layer; removing portions of the planarization layer unprotected by the second etch stop layer using the dry etching process to form a multilayered structure; and disposing a scintillator layer on the multilayered structure.

In one aspect of the specification, an organic x-ray detector fabricated by the process is provided. One aspect presents an x-ray system including the organic x-ray detector.

In one aspect of the specification, a process for fabricating an organic x-ray detector includes providing an array of thin film transistor assemblies, each thin film transistor assembly including a first electrode layer disposed on a thin film transistor; disposing an organic semiconductor layer on the array; disposing a second electrode layer including a first inorganic material on the organic semiconductor layer through a shadow mask to form a first etch stop layer; removing portions of the organic semiconductor layer unprotected by the first etch stop layer using a dry etching process to form a multilayered structure; and disposing a scintillator layer on the multilayered structure.

### DRAWINGS

These and other features, aspects, and advantages of the present disclosure will become better understood when the following detailed description is read with reference to the accompanying drawings in which like characters represent like parts throughout the drawings, wherein:

FIG. 1 is a flow chart of a process for forming an organic photodetector, in accordance with one embodiment;

FIG. 2 schematically represents the process steps of the process of FIG. 1, in accordance with one embodiment;

FIG. 3 schematically represents the process steps of the process of FIG. 1, in accordance with another embodiment;

FIG. 4 is a schematic view of a multilayered structure, in accordance with one embodiment;

FIG. 5 schematically represents the process steps of the process of FIG. 1, in accordance with one embodiment;

FIG. 6 is a schematic view of a multilayered structure, in accordance with one embodiment;

FIG. 7 is a flow chart of a process for fabricating an organic photodetector, in accordance with one embodiment;

FIG. 8 is a flow chart of a process for fabricating an organic x-ray detector, in accordance with one embodiment;

FIG. 9 is a schematic view of an organic x-ray detector, in accordance with one embodiment; and

FIG. 10 is a schematic of an x-ray system, in accordance with one embodiment.

### DETAILED DESCRIPTION

As discussed in detail below, some of the embodiments of the present disclosure relate to processes for fabricating an organic photodetector. More particularly, some embodiments relate to processes for fabricating an organic x-ray detector.

In the following specification and the claims, the singular forms “a”, “an” and “the” include plural referents unless the context clearly dictates otherwise. As used herein, the term “or” is not meant to be exclusive and refers to at least one of the referenced components being present and includes instances in which a combination of the referenced components may be present, unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

Unless defined otherwise, technical and scientific terms used herein have the same meaning as is commonly understood by one of skill in the art to which this invention belongs. The terms “comprising,” “including,” and “having” are intended to be inclusive, and mean that there may be additional elements other than the listed elements. The terms “first”, “second”, and the like, as used herein do not denote any order, quantity, or importance, but rather are used to distinguish one element from another.

As used herein, the term “layer” refers to a material disposed on at least a portion of an underlying surface in a continuous or discontinuous manner Further, the term “layer” does not necessarily mean a uniform thickness of the disposed material, and the disposed material may have a uniform or a variable thickness. As used herein, the term “disposed on” refers to layers disposed directly in contact with each other or indirectly by having intervening layers there between, unless otherwise specifically indicated.

In the present disclosure, when a layer is being described as “on” another layer or substrate, it is to be understood that the layers can either be directly contacting each other or have one (or more) layer or feature between the layers. Further, the term “on” describes the relative position of the layers to each other and does not necessarily mean “on top of” since the relative position above or below depends upon the orientation of the device to the viewer. Moreover, the use of “top,” “bottom,” “above,” “below,” and variations of these terms is made for convenience, and does not require any particular orientation of the components unless otherwise stated.

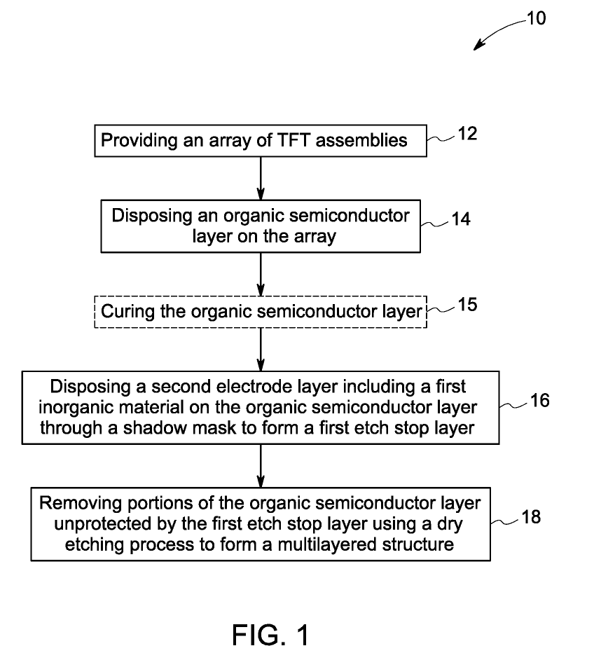

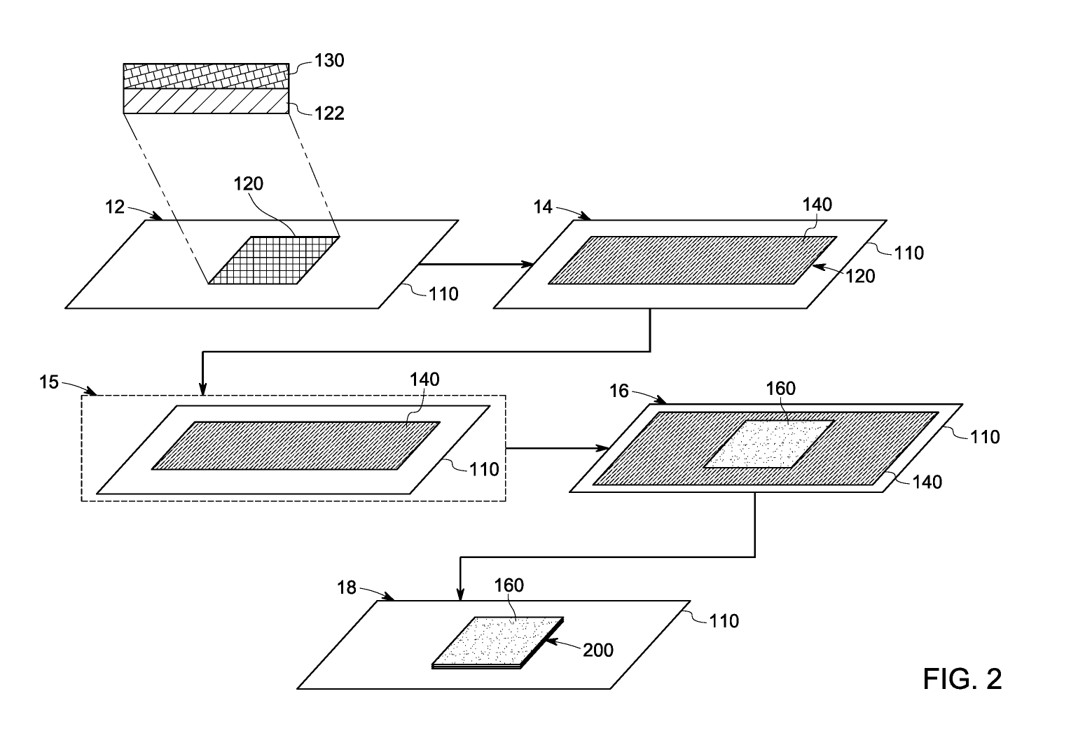

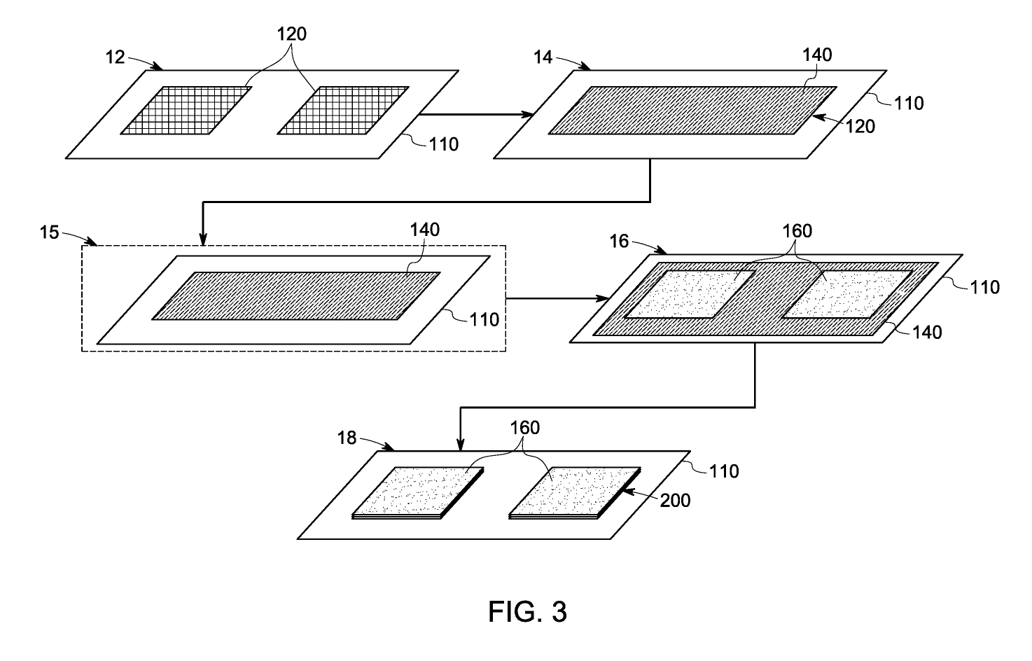

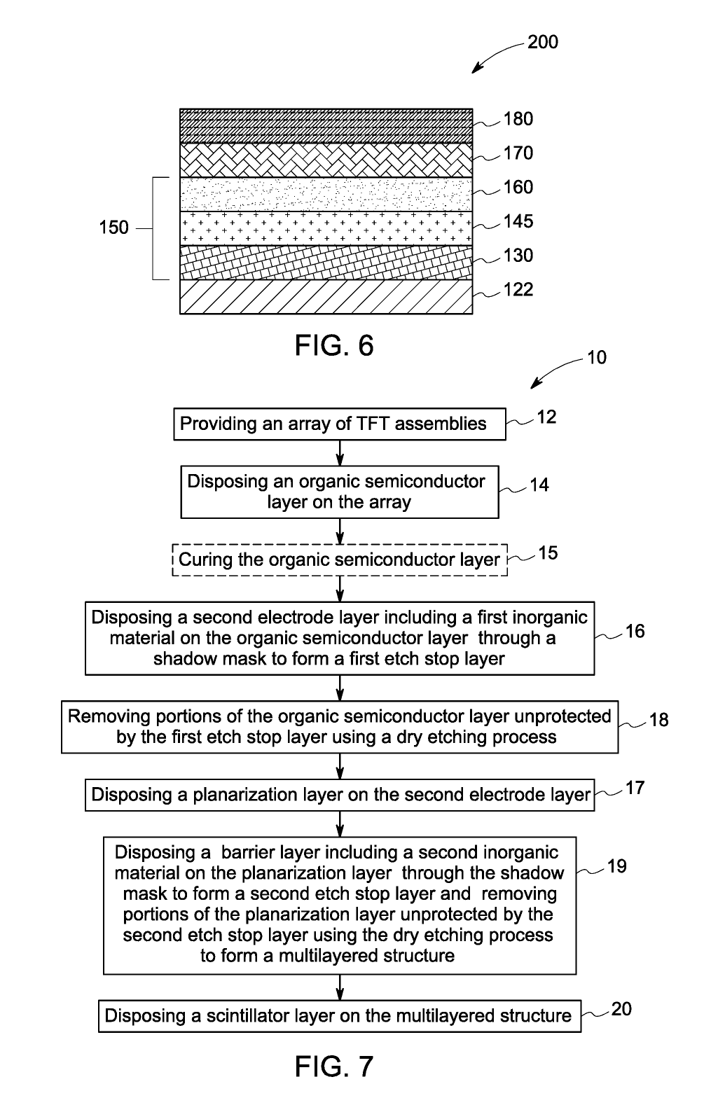

Some embodiments of the present disclosure are directed to a process for fabricating an organic photodetector such as, but not limited to, an organic x-ray detector. In some embodiments, the process for fabricating an organic photodetector is described with reference to FIGS. 1-3. FIG. 1 shows a flow chart of a process 10 for fabricating an organic photodetector 100 (for example, as shown in FIG. 6), in accordance with some embodiments. The process steps of the process 10 are schematically represented in FIGS. 2 and 3, according to some embodiments.

Referring to FIGS. 1-2, in some embodiments, the process 10 includes the step 12 of providing an array of thin film transistor (TFT) assemblies 120, the step 14 of disposing an organic semiconductor layer 140 on the array of TFT assemblies 120, the step 16 of disposing a second electrode layer 160 including a first inorganic material on the organic semiconductor layer 140 through a shadow mask to form a first etch stop layer, and step 18 of removing portions of the organic semiconductor layer 140 unprotected by the first etch stop layer using a dry etching process to form a multilayered structure 200.

In some embodiments, as schematically depicted in FIG. 3, the process 10 may include the step 12 of providing a plurality of arrays of TFT assemblies 120 on a substrate 110. In these embodiments, the process 10 includes the step 14 of disposing the organic semiconductor layer 140 (for example, a large area organic semiconductor layer) on the plurality of arrays of TFT assemblies 120, and the step 16 of disposing the second electrode layer 160 on the organic semiconductor layer 140 through a shadow mask to form a first etch stop layer 160. The process 10, in these embodiments, includes forming a plurality of multilayered structures 200 on the substrate 110 after the completion of the step 18 of removing portions of the organic semiconductor layer 140 unprotected by the first etch stop layer 160 using the dry etching process.

The array of TFT assemblies 120 may include a TFT array 122 (including a plurality of TFTs) and a first electrode layer 130 disposed on the TFT array 122, as shown in the exploded view of the array of TFT assemblies 120 of FIG. 2. In some embodiments, each TFT assembly in the array of TFT assemblies 120 may include the first electrode layer 130 disposed on a thin film transistor (TFT) (not shown individually in figures). In such instances, the first electrode layer may be disposed on a TFT array including a plurality of TFTs in a continuous manner The first electrode layer 130 may be disposed on the TFT array 122 by any suitable technique, such as sputtering, vapor deposition, and e-beam deposition.

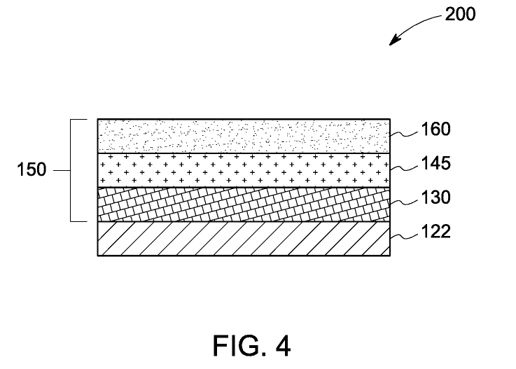

The multilayered structure 200 is schematically shown in FIG. 4. As illustrated in FIG. 4, in some embodiments, the multilayered structure 200 includes the TFT array 122, the first electrode layer 130 disposed on the TFT array 122, a patterned organic semiconductor layer 145 disposed on the first electrode layer 130, and a second electrode layer 160 disposed on the patterned organic semiconductor layer 145. As used herein, the term “patterned organic semiconductor layer” refers to a layer that is formed by etching out portions of the organic semiconductor layer 140 not protected by a first etch stop layer. In some embodiments, the patterned organic semiconductor layer 145 is aligned with the array of TFT assemblies 120.

In one embodiment, the organic semiconductor layer 140 includes an organic absorber layer, which may also be referred to as an “active layer.” The first electrode layer 130, the patterned organic semiconductor layer 145, and the second electrode layer 160 may form an organic photodiode 150 that is disposed on the TFT array 122. In some embodiments, an array of organic photodiodes 150 is formed on the TFT array 122 to form an array of multilayered structures 200 such that each multilayered structure includes an organic photodiode 150 disposed on at least one TFT of the TFT array 120. For example, an organic photodiode 150 may be disposed on one or more rows or columns of TFT array.

In some embodiments, an array of organic photodiodes 150 is formed on the plurality of TFT arrays 122 to form an array of multilayered structures 200 such that each multilayered structure includes an organic photodiode 150 disposed on the TFT array 120.

In some embodiments, the TFT array 122 may include a two dimensional array of passive or active pixels, which stores charge for read out by electronics, disposed on a layer formed of amorphous silicon, poly-crystalline silicon, an amorphous metal oxide, or organic semiconductors. In some embodiments, the TFT array includes TFTs including amorphous silicon, poly-crystalline silicon, amorphous metal oxide, or organic molecules. Suitable examples of the amorphous metal oxides include zinc oxide, zinc tin oxide, indium oxides, indium zinc oxides (In—Zn—O series), indium gallium oxides, gallium zinc oxides, indium silicon zinc oxides, and indium gallium zinc oxides (IGZO). IGZO materials include InGaO₃(ZnO)ₘ where m is <6 and InGaZnO₄. Suitable examples of the organic semiconductors include, but are not limited to, conjugated aromatic materials, such as rubrene, tetracene, pentacene, perylenediimides, tetracyanoquinodimethane and polymeric materials such as polythiophenes, polybenzodithiophenes, polyfluorene, polydiacetylene, poly(2,5-thiophenylene vinylene), poly(p-phenylene vinylene), and derivatives thereof.

As discussed above, the array of TFT assemblies 120 may be disposed on the substrate 110. Suitable substrate materials include glass, ceramics, plastics, metals or combinations thereof. The substrate may be present as a rigid sheet such as a thick glass, a thick plastic sheet, a thick plastic composite sheet, and a metal plate; or a flexible sheet, such as, a thin glass sheet, a thin plastic sheet, a thin plastic composite sheet, and metal foil. Examples of suitable materials for the substrate include glass, which may be rigid or flexible; plastics such as polyethylene terephthalate, polybutylene phthalate, polyethylene naphthalate, polystyrene, polycarbonate, polyether sulfone, polyallylate, polyimide, polycycloolefin, norbornene resins, and fluoropolymers; metals such as stainless steel, aluminum, silver and gold; metal oxides such as titanium oxide and zinc oxide; and semiconductors such as silicon. In certain embodiments, the substrate includes a polycarbonate.

As noted, the organic semiconductor layer 140 may include an organic absorber layer. The organic absorber layer may be a bulk, hetero-junction organic photodiode layer that absorbs light, generates electron-hole pairs (excitons), and transports charge (holes and electrons) to the contact layers (electrode layers). The organic absorber layer may include a blend of a donor material and an acceptor material; more than one donor or acceptor material may be included in the blend. Further, the HOMO/LUMO levels of the donor and acceptor materials may be compatible with that of the first and second electrode layers (130, 160) in order to allow efficient charge extraction without creating an energetic barrier.

Suitable donor materials include low bandgap polymers having LUMO ranging from about 1.9 eV to about 4.9 eV and HOMO ranging from about 2.9 eV to about 7 eV. In some embodiments, the donor material has LUMO in a range from 2.5 eV to 4.5 eV, and in certain embodiments, from 3.0 eV to 4.5 eV. In some embodiments, the donor material has HOMO in a range from 4.0 eV to 6 eV, and in certain embodiments, from 4.5 eV to 6 eV. The low band gap polymers include conjugated polymers and copolymers composed of units derived from substituted or unsubstituted monoheterocyclic and polyheterocyclic monomers such as thiophene, fluorene, phenylenvinylene, carbazole, pyrrolopyrrole, and fused heteropolycyclic monomers containing the thiophene ring, including, but not limited to, thienothiophene, benzodithiophene, benzothiadiazole, pyrrolothiophene monomers, and substituted analogs thereof. In some embodiments, the low band gap polymers include units derived from substituted or unsubstituted thienothiophene, benzodithiophene, benzothiadiazole, carbazole, isothianaphthene, pyrrole, benzobis(thiadiazole), thienopyrazine, fluorene, thiadiazolequinoxaline, or combinations thereof. In the context of the low band gap polymers described herein, the term “units derived from” means that the units include monoheterocyclic and polyheterocyclic group, without regard to the substituents present before or during the polymerization; for example, “the low band gap polymers include units derived from thienothiophene” means that the low band gap polymers include divalent thienothiophenyl groups. Examples of suitable materials for use as low bandgap polymers in the organic photodetectors, in some embodiments, include copolymers derived from substituted or unsubstituted thienothiophene, benzodithiophene, benzothiadiazole, carbazole monomers, or combinations thereof, such as poly[[4,8-bis[2-ethylhexyl)oxy]benzo[1,2-b:4,5-b′]dithiophene-2,6-diyl][3-fluoro-2-[(2-ethylhexyl)carbonyl]thieno[3,4-b]thiophenediyl (PTB7); 2,1,3-benzothiadiazole-4,7-diyl[4,4-bis(2-ethylhexyl)-4H-cyclopenta[2,1-b:3,4-b′]dithiophene-2,6-diyl (PCPDTBT); poly[[9-(1-octylnonyl)-9H-carbazole-2,7-diyl]-2,5-thiophenediyl-2,1,3-benzothiadiazole-4,7-diyl-2,5-thiophenediyl] (PCDTBT); poly[(4,40-bis(2-ethylhexyl)dithieno[3,2-b:20,30-d]silole)-2,6-diyl-alt-(2,1,3-benzo-thiadiazole)-4,7-diyl] (PSBTBT); poly((4,8-bis(octyloxy)benzo(1,2-b:4,5-b′)dithiophene-2,6-diyl)(2-((dodecyloxy)carbonyl)thieno(3,4-b)thiophenediyl)) (PTB1); poly((4,8-bis(octyloxy)benzo(1,2-b:4,5-b′)dithiophene-2,6-diyl)(2-((ethylhexyloxy)carbonyl)thieno(3,4-b)thiophenediyl)) (PTB2); poly((4,8-bis(octyl)benzo(1,2-b:4,5-b′)dithiophene-2,6-diyl)(2-((ethylhexyloxy)carbonyl)thieno(3,4-b)thiophenediyl)) (PTB3); poly((4,8-bis-(ethylhexyloxybenzo(1,2-b:4,5-b′)dithiophene-2,6-diyl)(2-((octyloxy)carbonyl)-3-fluoro)thieno(3,4-b)thiophenediyl)) (PTB4); poly((4,8-bis(ethylhexyloxybenzo(1,2-b:4,5-b′)dithiophene-2,6-diyl)(2-((octyloxy)carbonyl)thieno(3,4-b)thiophenediyl)) (PTB5); poly((4,8-bis(octyloxy)benzo(1,2-b:4,5-b′)dithiophene-2,6-diyl)(2-((butyloctyloxy)carbonyl)thieno(3,4-b)thiophenediyl)) (PTB6); poly[[5-(2-ethylhexyl)-5,6-dihydro-4,6-dioxo-4H-thieno[3,4-c]pyrrole-1,3-diyl][4,8-bis[(2-ethylhexyl)oxy]benzo[1,2-b:4,5- b′]dithiophene-2,6-diyl]](PBDTTPD); poly[1-(6-{4,8-bis[(2-ethylhexyl)oxy]-6-methylbenzo[1,2-b:4,5-b′]dithiophen-2-yl}-3-fluoro-4-methylthieno[3,4-b]thiophen- 2-yl)-1-octanone] (PBDTTT-CF); or poly[2,1,3-benzothiadiazole-4,7-diyl-2,5-thiophenediyl (9,9-dioctyl-9H-9-silafluorene-2,7-diyl)-2,5 -thiophenediyl] (PSiF-DBT). Other suitable materials include poly[5,7-bis(4-decanyl-2-thienyl)thieno[3,4-b]diathiazolethiophene-2,5] (PDDTT); poly[2,3-bis(4-(2-ethylhexyloxy)phenyl)-5,7-di(thiophen-2-yl)thieno[3,4-b]pyrazine] (PDTTP); or polythieno[3,4-b]thiophene (PTT). In certain embodiments, suitable materials are copolymers derived from substituted or unsubstituted benzodithiophene monomers, such as the PTB1-7 series and PCPDTBT; or benzothiadiazole monomers, such as PCDTBT and PCPDTBT.

Suitable acceptor materials include fullerenes and their derivatives such as [6,6]-phenyl-C₆₁-butyric acid methyl ester (PCBM); PCBM analogs such as PC₇₀BM, PC₇₁BM, PC₈₀BM, bis-adducts thereof, such as bis-PC₇₁BM, indene mono-adducts thereof, such as indene-C₆₀ monoadduct (ICMA) or indene bis-adducts thereof, such as indene-C₆₀ bisadduct (ICBA). Other materials such as poly[(9,9-dioctylfluorenyl-2,7-diyl)-alt-(4,7-bis(3-hexylthiophen-5-yl)-2,1,3-benzothiadiazole)-2′,2″-diyl] (F8TBT) may also be used, alone or with a fullerene derivative.

Depending on the application and variations in design, the organic photodiode 150 may include multiple organic semiconductor layers. In some embodiments, the organic photodiode 150 may further include one or more charge blocking layers, for example, an electron blocking layer and a hole blocking layer (not shown in Figures). In some embodiments, an electron blocking layer may be disposed between the first electrode layer 130 and the organic absorber layer. In some embodiments, a hole blocking layer may be disposed between the organic absorber layer and the second electrode layer 160. Further, the organic photodiode 150 may be directly disposed on the TFT array 122 or the design may include one or more layers disposed between the organic photodiode 150 and the TFT array 122.

In some embodiments, the first electrode layer 130 functions as a cathode and the second electrode layer 160 functions as an anode. In some other embodiments, the first electrode layer 130 functions as an anode and the second electrode layer 160 functions as a cathode.

In some embodiments, the first electrode layer 130 includes an anode material. Suitable anode materials include, but are not limited to, metals such as Al, Ag, Au, and Pt; metal oxides such as indium tin oxide (ITO), indium zinc oxide (IZO), and zinc oxide (ZnO). In some embodiments, the anode material may include organic conductors such as p-doped conjugated polymers like PEDOT.

As noted, the second electrode layer 160 includes a first inorganic material. In some embodiments, the first inorganic material may be suitable to function as a cathode material. Suitable examples of first inorganic materials include, but are not limited to, a metal oxide or a metal in elemental form. In some embodiments, the second electrode layer 160 includes ITO. Examples of metals may include gold, silver, aluminum, calcium, magnesium or combinations thereof. Suitable metal oxides include transparent conductive oxides (TCO). Examples of suitable TCO include indium tin oxide (ITO), indium zinc oxide (IZO), aluminum zinc oxide (AZO), fluorinated tin oxide (FTO), tin oxide (SnO₂), titanium dioxide (TiO₂), ZnO, indium gallium oxide, gallium zinc oxide, indium silicon zinc oxide, indium gallium zinc oxide, or combinations thereof. The first inorganic material, for example ITO may provide a barrier for oxygen plasma to serve as a first etch stop layer for the dry etching process, and also serve as the second electrode layer 160. In some embodiments, the first inorganic material includes a dielectric material such as silicon oxide, silicon nitride, aluminum oxide. In some embodiments, the second electrode layer 160 includes a layer of the dielectric material disposed on the metal oxide, for example ITO. In some embodiments, the second electrode layer 160 includes a layer of the dielectric material disposed on the metal, for example aluminum. The dielectric material may further provide a good barrier for oxygen plasma to protect the underlying materials such as the metal oxide and the organic semiconductor layer.

Referring to FIGS. 1-2 again, in some embodiments, the process 10 includes the step 12 of providing the array of TFT assemblies 120. The step 12 of providing the array of TFT assemblies 120 may include either procuring pre-fabricated array of TFT assemblies or forming the array of TFT assemblies by disposing the first electrode layer 130 on the TFT array 122.

In some embodiments, the process 10 includes the step 14 of disposing an organic semiconductor layer 140 on the array of TFT assemblies 120, as shown in FIG. 3. In some embodiments, the step 14 of disposing the organic semiconductor layer 140 includes disposing the organic absorber layer. In some embodiments, the step 14 of disposing the organic semiconductor layer 140 includes disposing a large area organic semiconductor layer (in form of a blanket coating) on the plurality of arrays of TFT assemblies 120 as shown in FIG. 3.

In some embodiments, the organic semiconductor layer 140 is disposed using any suitable method, for example a solution based deposition method. Non-limiting examples of the deposition methods for disposing the organic semiconductor layer 140 may include one or more of solvent casting, spin coating, slot die coating, dip coating, spray coating, blade coating, inkjet printing or any other solution based methods.

In some embodiments, the step 14 of disposing the organic semiconductor layer 140 further includes one or more steps of disposing the electron blocking layer (not shown) and the hole blocking layer (not shown). The electron blocking layer may be disposed on the first electrode layer 130 before disposing the organic absorber layer, by a suitable technique. In embodiments where the electron blocking layer is disposed on the first electrode layer 130, the organic absorber layer is disposed on the electron blocking layer. In some embodiments, the hole blocking layer is disposed on the organic absorber layer before disposing the second electrode layer 160, by any suitable technique. In these embodiments, the second electrode layer 160 may be disposed directly on the hole blocking layer.

Following the deposition of the organic semiconductor layer 140, the process may further include the step 15 of curing the organic semiconductor layer 140 to remove a solvent that may be used while disposing the organic semiconductor layer 140 by a solution based method. In some embodiments, the step of curing the organic semiconductor layer 140 is carried out at a temperature in a range from about 50 degrees Celsius to about 300 degrees Celsius for at least 10 minutes. In certain embodiments, the organic absorber layer may be cured at a temperature in a range from about 100 degrees Celsius to about 200 degrees Celsius for at least 1 hour. In embodiments where a plurality of organic semiconductor layers is disposed, the disposition of one or more organic semiconductor layers may be followed by a curing step.

The process 10 may further include the step 16 of disposing the second electrode layer 160 on the organic semiconductor layer 140. The step 16 of disposing the second electrode layer 160 includes disposing the second electrode layer through a shadow mask to form a first etch stop layer. The second electrode layer 160 may be disposed by any suitable deposition technique, such as thermal evaporation, electron beam evaporation, sputtering or direct printing. The first etch stop layer may provide a barrier for reactive ions (for example, oxygen plasma) used in a dry etching process, and serve as a protecting layer for the underlying layers from the dry etching process. The second electrode layer 160 may be disposed in such a way that the first etch stop layer is aligned with the array of TFT assemblies 120 (FIG. 2), and in some embodiments, with the plurality of arrays of TFT assemblies (FIG. 3). That is, in these instances, the portions of the organic semiconductor layer 140 not covering the array(s) of TFT assemblies 120, are not protected by the first etch stop layer. In some other embodiments, the first etch stop layer may be aligned with one or more TFT assemblies or a portion of the array of the TFT assemblies 120.

The process 10 further includes the step 18 of removing portions of the organic semiconductor layer 140 unprotected by the first etch stop layer using a dry etching process to form the multilayered structure 200. In some embodiments, the process 10 includes completely removing the portions of the organic semiconductor layer 140 unprotected by the first etch stop layer using the dry etching process. After completion of the step 18, a patterned organic semiconductor layer 145 aligned with the array of TFT assemblies 120 may be formed, as shown in FIG. 2. In some embodiments, the completion of step 18 may result in formation of a multilayered structure 200 including a photodiode 150 disposed on the TFT array 122, as shown in FIG. 4. In some embodiments, an array of multilayered structures 200 may be formed, each multilayered structure 200 including a photodiode 150 disposed on the TFT array 122 or a portion of the TFT array 122.

Moreover, in some embodiments, as shown in FIG. 3, the step 18 may result in formation of a plurality of multilayered structures 200 corresponding to the plurality of arrays of TFT assemblies 120. These plurality of multilayered structures may be separated by slitting the substrate 110, and individual multilayered structures 200 may be used to form organic photodetectors, for example organic x-ray detectors.

As used herein, the term “dry etching process” refers to removal of a material by exposing the material to a bombardment of ions that dislodges the material from the unprotected portions (that is, the portions not protected by a etch stop layer). The ions, generally, include plasma of one or more reactive gases such as fluorocarbons, oxygen, chlorine, boron trichloride, or their combinations with nitrogen, argon, helium or other gases. In some embodiments, the dry etching process includes a reactive ion etching process, for example using an oxygen plasma etching process. Unlike chemical etchants used in wet etching, the dry etching process may result in etching directionally or anisotropically.

Without being bound by any theory, it is believed that the process for fabricating an organic photodetector, as described herein, may advantageously allow use of single coating platform of organic semiconductor layers (i.e., blanket coating) on the plurality of arrays of TFT assemblies. The process enables patterning multiple panels (i.e., multilayered structures) simultaneously on one substrate and provides uniform OPD layers with well-defined edge profile by removing the portions of the organic semiconductor layers using the dry etching process. Furthermore, in some embodiments, the process may allow use of an electrode layer as an etch stop layer to etch off organic semiconductor layer(s) with reduced or no damage of the OPD layers or degradation of OPD performance.

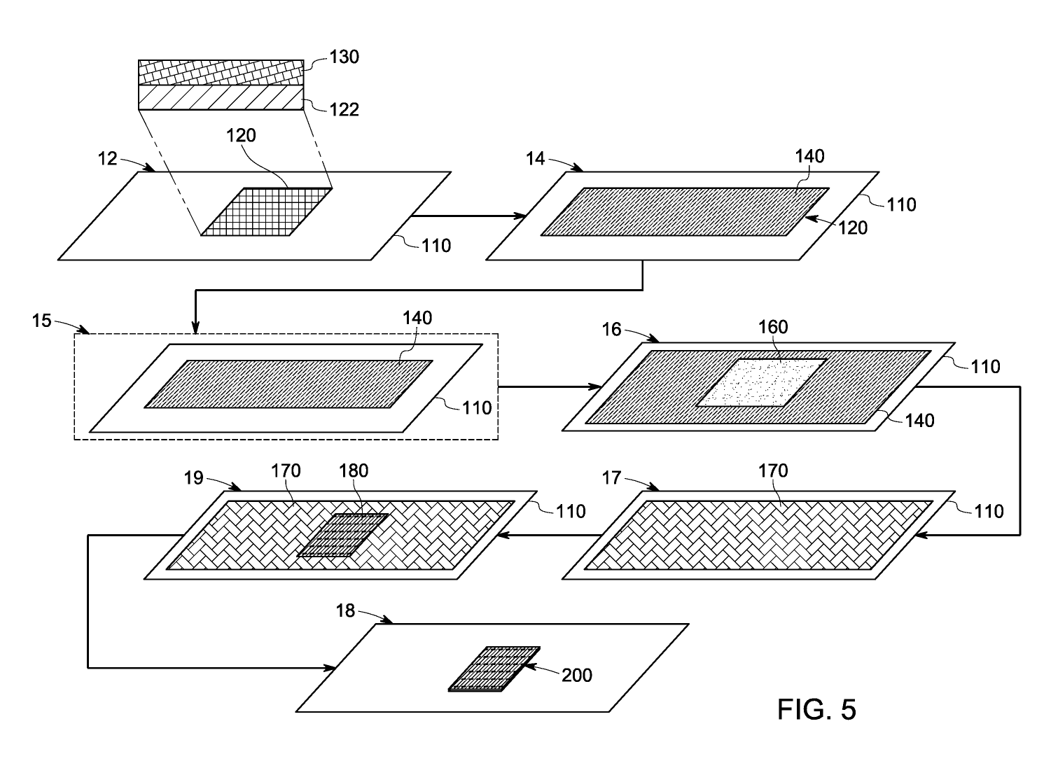

In some embodiments, as shown in FIG. 5, the process 10 may further include the step 17 of disposing a planarization layer 170 on the second electrode layer 160 and the step 19 of disposing a barrier layer 180 including a second inorganic material on the planarization layer through the shadow mask to form a second etch stop layer. The step 17 and 19 may be carried out before or after the step 18 of removing portions of the organic semiconductor layer. In some embodiments, the second etch stop layer 180 is aligned with the first etch stop layer 160.

In some embodiments, the process further includes the step of removing portions of the planarization layer 170 unprotected by the second etch stop layer 180 using the dry etching process during or after the step 18 of removing portions of the organic semiconductor layer. In some embodiments, the step of removing the portions of the planarization layer 170 and the step of removing the portions of the organic semiconductor layer 140 may be performed simultaneously using the dry etching process. In some other embodiments, the step 18 of removing the portions of the organic semiconductor layer 140 may be performed before the steps 17 and 19. In these embodiments, the step 19 further includes removing the portions of the planarization layer 170 by performing additional etching process step using the dry etching process. In these embodiments, the completion of step 18, step 19 or both may result in formation of a multilayered structure 200 including a photodiode 150 disposed on the TFT array 122, the planarization layer 170 disposed on the photodiode 150 and the barrier layer 180 disposed on the planarization layer 170 as shown in FIG. 6.

Non-limiting examples of materials for the planarization layer 170 include a polyimide, an acrylate, or a low solvent content silicone. The planarization layer 170 may provide a smooth surface on the multilayered structure 200 prior to the deposition of the scintillator layer 190.

As noted, the barrier layer 180 includes a second inorganic material. The first inorganic material and the second inorganic material may be same or different. In some embodiments, the second inorganic material may include a metal oxide, a metal nitride, or combinations thereof, where the metal is one of indium, tin, zinc, titanium, and aluminum. Non-limiting examples of metal nitrides and metal oxides include indium zinc oxide (IZO), indium tin oxide (ITO), aluminum oxide, aluminum oxynitride, zinc oxide, indium oxide, tin oxide, cadmium tin oxide, cadmium oxide, magnesium oxide, titanium nitride or combinations thereof. In certain embodiments, the barrier layer 180 may include silicon oxide, silicon nitride, silicon oxynitride or combinations thereof.

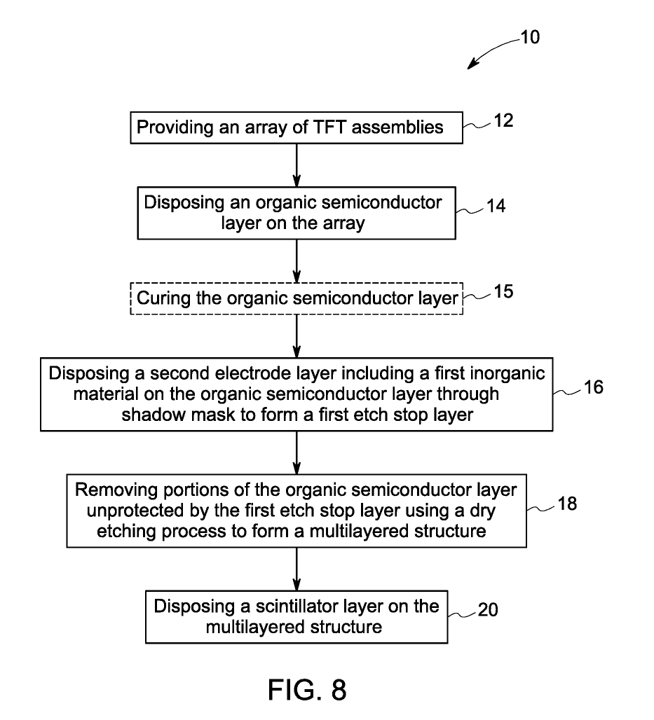

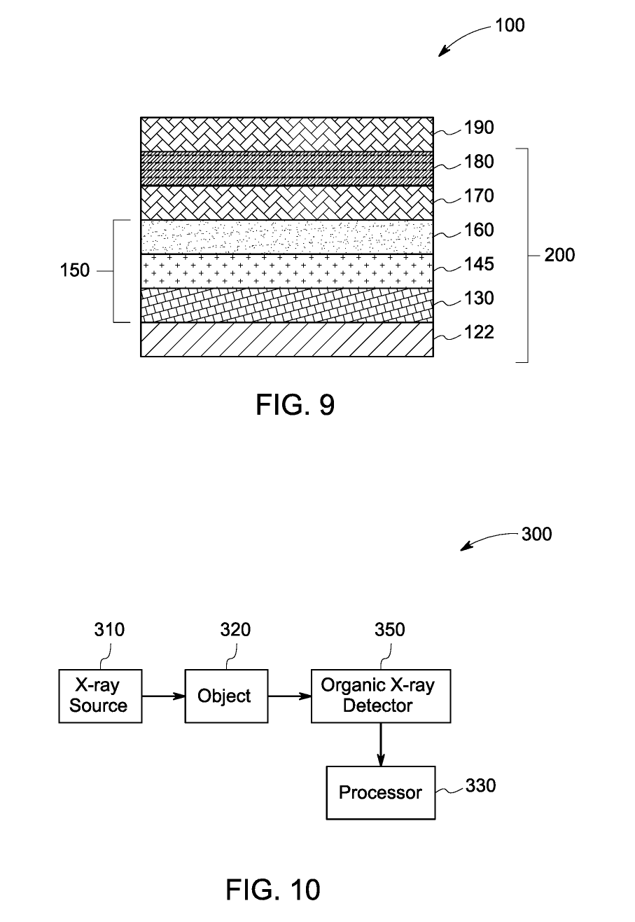

In some embodiments, the process 10 as described in FIG. 1-3 or 5 may further include the step 20 of disposing a scintillator layer 190 on a multilayered structure 200, as shown in flow charts of FIGS. 7 and 8. FIG. 9 illustrates an organic photodetector 100, according to some embodiments, which includes the scintillator layer 190 disposed on the multilayered structure 200. The scintillator layer 190 may be disposed by depositing a suitable scintillator material or by providing a suitable scintillator sheet.

The scintillator layer 190 may include a phosphor material that is capable of converting x-rays to visible light. The wavelength range of light emitted by scintillator layer may range from about 360 nanometers (nm) to about 830 nm. Suitable materials for the scintillator layer include, but are not limited to, cesium iodide (CsI), gadolinium oxysulfide (GOS), sodium iodide (NaI), lutetium oxides (Lu₂O₃), or combinations thereof. Some examples include CsI (Tl) (cesium iodide to which thallium has been added) and terbium-activated gadolinium oxysulfide (GOS). Such materials are commercially available in the form of a sheet or screen. The scintillator layer can be applied via direct deposition such as thermal evaporation or lamination. In some embodiments, the scintillator layer may be a PIB (particle in binder) scintillator, where scintillating particles may be incorporated in a binder matrix material and flattened on a substrate. The scintillator layer may be a monolithic scintillator or pixelated scintillator array. The visible light generated by the scintillator layer 190 irradiates the organic photodiode 150 disposed on the TFT array 120. In some embodiments, the scintillator layer is excited by impinging x-ray radiation, and produces visible light.

In certain embodiments, the organic photodetector 100 may be an organic x-ray detector. The x-ray detector may be fabricated by the process 10 (FIGS. 1-3, 5, 7-8), as described herein.

In some embodiments, a process for fabricating an organic x-ray detector is provided. The process includes providing an array of thin film transistor assemblies, each including a first electrode layer disposed on a thin film transistor; disposing an organic semiconductor layer on the array of thin film transistor assemblies; disposing a second electrode layer including a first inorganic material on the organic semiconductor layer through a shadow mask to form a first etch stop layer; removing portions of the organic semiconductor layer unprotected by the first etch stop layer using a dry etching process to form a multilayered structure; and disposing a scintillator layer on the multilayered structure.

In some embodiments, an x-ray system is also presented. As shown in FIG. 10, an x-ray system 300 includes an x-ray source 310 configured to irradiate an object 320 with x-ray radiation; an organic x-ray detector 350, and a processor 330 operable to process data from the organic x-ray detector 350.

An organic photodetector, for example an x-ray detector according to embodiments of the present disclosure may be used in imaging systems, for example, in conformal imaging, with the photodetector in intimate contact with the imaging surface. For parts with internal structure, the photodetector may be rolled or shaped to contact the part being imaged. Applications for the organic photodetectors according to some embodiments of the present disclosure include security imaging; medical imaging; and industrial and military imaging for pipeline, fuselage, airframe and other tight access areas.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A process for fabricating an organic photodetector, comprising:
providing an array of thin film transistor assemblies, each thin film transistor assembly comprising a first electrode layer disposed on a thin film transistor;
disposing an organic semiconductor layer on the array;
disposing a second electrode layer comprising a first inorganic material on the organic semiconductor layer through a shadow mask to form a first etch stop layer; and
removing portions of the organic semiconductor layer unprotected by the first etch stop layer using a dry etching process to form a multilayered structure.

2. The process according to claim 1, wherein the dry etching process comprises etching using oxygen plasma.

3. The process according to claim 1, wherein the first inorganic material comprises a metal oxide or a metal in elemental form.

4. The process according to claim 3, wherein the metal oxide comprises a transparent conductive oxide selected from the group consisting of tin oxide, zinc oxide, indium tin oxide, indium zinc oxide, and combinations thereof.

5. The process according to claim 1, wherein the first inorganic material comprises a dielectric material.

6. The process according to claim 5, wherein the dielectric material comprises silicon oxide, silicon nitride, aluminum oxide, or combinations thereof.

7. The process according to claim 1, wherein the organic semiconductor layer comprises a fullerene or a fullerene derivative.

8. The process according to claim 1, wherein the organic semiconductor layer comprises a conjugated polymer.

9. The process according to claim 1, further comprising:
disposing a planarization layer on the second electrode layer; and
disposing a barrier layer comprising a second inorganic material on the planarization layer through the shadow mask to form a second etch stop layer before or after the step of removing portions of the organic semiconductor layer.

10. The process according to claim 9, further comprising removing portions of the planarization layer unprotected by the second etch stop layer using the dry etching process during or after the step of removing portions of the organic semiconductor layer.

11. The process according to claim 1, further comprising disposing a scintillator layer on the multilayered structure.

12. An organic photodetector fabricated by the process in accordance with claim 1.

13. A process for fabricating an organic photodetector, comprising:
providing an array of thin film transistor assemblies, each thin film transistor assembly comprising a first electrode layer disposed on a thin film transistor;
disposing an organic semiconductor layer on the array;
disposing a second electrode layer comprising a first inorganic material on the organic semiconductor layer through a shadow mask to form a first etch stop layer;
removing portions of the organic semiconductor layer unprotected by the first etch stop layer using a dry etching process;
disposing a planarization layer on the second electrode layer;
disposing a barrier layer comprising a second inorganic material on the planarization layer through the shadow mask to form a second etch stop layer;
removing portions of the planarization layer unprotected by the second etch stop layer using the dry etching process to form a multilayered structure; and
disposing a scintillator layer on the multilayered structure.

14. A process for fabricating an organic x-ray detector, comprising:
providing an array of thin film transistor assemblies, each thin film transistor assembly comprising a first electrode layer disposed on a thin film transistor;
disposing an organic semiconductor layer on the array;
disposing a second electrode layer comprising a first inorganic material on the organic semiconductor layer through a shadow mask to form a first etch stop layer;
removing portions of the organic semiconductor layer unprotected by the first etch stop layer using a dry etching process to form a multilayered structure; and
disposing a scintillator layer on the multilayered structure.

15. The process according to claim 14, wherein the scintillator layer comprises cesium iodide (CsI), gadolinium oxysulfide (GOS), lutetium oxide (Lu₂O₃) or combinations thereof.

16. An organic x-ray detector fabricated by the process in accordance with claim 14.

17. An x-ray system comprising the organic x-ray detector in accordance with claim 16.
